(19) United States
(12) Patent Application Publication
(10) Pub. No.: US 2017/0003171 A1
(43) Pub. Date: Jan. 5, 2017

(54) TEMPERATURE MEASURING METHOD AND HEAT PROCESSING APPARATUS

(71) Applicant: TOKYO ELECTRON LIMITED, Tokyo (JP)

(72) Inventors: Yuki WADA, Oshu-shi (JP); Koji YOSHII, Oshu-shi (JP); Kazuteru OBARA, Oshu-shi (JP)

(21) Appl. No.: 15/191,602

(22) Filed: Jun. 24, 2016

(30) Foreign Application Priority Data
Jun. 30, 2015 (JP) 2015-130756
Apr. 20, 2016 (JP) 2016-084733

(51) Int. Cl. G01J 5/00; H01L 21/687; H01L 21/66; G01J 5/10; H01L 21/67

(52) U.S. Cl. CPC G01J 5/0007; G01J 5/10; H01L 21/67248; H01L 22/10; H01L 21/68764; H01L 21/67098; G01J 2005/0081

(57) ABSTRACT

A temperature measuring method for measuring a temperature in a processing vessel of a semiconductor manufacturing apparatus by a radiation temperature measurement part, which is configured to measure a temperature by detecting infrared rays radiated from an object, includes: detecting infrared rays radiated from a low resistance silicon wafer having a resistivity of 0.02 Ω·cm or less at room temperature (20 degrees C.) by the radiation temperature measurement part.

### CROSS-REFERENCE TO RELATED APPLICATIONS

This application claims the benefit of Japanese Patent Application Nos. 2015-130756, filed on Jun. 30, 2015, and 2016-084733, filed on Apr. 20, 2016, in the Japan Patent Office, the disclosure of which is incorporated herein in their entirety by reference.

### TECHNICAL FIELD

The present disclosure relates to a temperature measuring method and a heat processing apparatus.

### BACKGROUND

There are heat processing apparatus in which semiconductor wafers (hereinafter, referred to as “wafers”) as a plurality of substrates are loaded on a rotary table in a rotational direction of the rotary table installed in a processing vessel. The heat processing apparatus includes a gas supply part installed in the diameter direction of the rotary table to supply a processing gas and a heater installed below the rotary table to heat wafers. In addition, the rotary table is rotated while the gas is ejected by the gas supply part and wafers are heated by the heater, thereby performing a film forming process on the wafers.

In this heat processing apparatus, the temperature measurement is performed to confirm whether the wafers are heated at an appropriate temperature. In a temperature measuring method, after a temperature-measuring purpose wafer having a thermocouple is loaded on the rotary table, the temperature of the heater is increased and a temperature of the temperature-measuring purpose water is measured by the thermocouple. In such a method, since the thermocouple is connected to the temperature-measuring purpose wafer, it is impossible to measure the temperature while the rotary table is rotated.

Therefore, a temperature measuring device is disclosed which is provided with a radiation temperature measurement part for measuring temperatures of a plurality of spot regions by repeatedly scanning a face of the rotary table in the diameter direction while the rotary table installed in the processing vessel rotates. In this temperature measuring device, wafers made of SiC (silicon carbide) (hereinafter, referred to as “SiC wafers”) are loaded on the rotary table and the infrared rays radiated from a surface of the SiC wafer are detected, thereby measuring temperatures.

In addition to SiC, silicon, quartz or the like is used as a target when temperatures are measured by the radiation temperature measurement part.

However, even when temperatures of a plurality of SiC waters loaded on the rotary table were measured in a state where a temperature within the processing vessel was stable, respective temperatures of the plurality of SiC wafers were different from one another, and thus, it was difficult to exactly measure the temperatures. It is thought that this is because a deviation in emissivity occurs for each wafer when the wafers are different in manufacturing history, such as the plurality of SiC wafers are respectively manufactured from different ingots from one another.

In addition, when silicon is used as a target when the temperature is measured by the radiation temperature measurement part, it is difficult to exactly measure a temperature in a low temperature region (for example, in a range of 200 degrees C. to 400 degrees C.). This is because silicon transmits infrared rays in the low temperature region. In addition, since SiC and quartz are different from silicon in thermal capacity or thermal behavior, it is difficult to estimate the temperature of silicon using SiC and quartz instead of silicon.

### SUMMARY

Some embodiments of the present disclosure provide a temperature measuring method capable of measuring temperatures of wafers with high precision even when wafers having different manufacturing histories are used.

According to one embodiment of the present disclosure, there is provided a temperature measuring method for measuring a temperature in a processing vessel of a semiconductor manufacturing apparatus by a radiation temperature measurement part, which is configured to measure a temperature by detecting infrared rays radiated from an object. The temperature measuring method includes detecting infrared rays radiated from a low resistance silicon wafer haying a resistivity of 0.02 Ω·cm or less at room temperature (20 degrees C.) by the radiation temperature measurement part.

According to another embodiment of the present disclosure, there is provided a temperature measuring method in a heat processing apparatus wherein a plurality of substrates are loaded on a surface of a rotary table installed in a processing vessel and a heat process is performed on the plurality of substrates while rotating the rotary table. The temperature measuring method includes: loading a plurality of low resistance silicon wafers having a resistivity of 0.02 Ω·cm or less at room temperature (20 degrees C.) on the surface of the rotary table; rotating the rotary table having the plurality of low resistance silicon wafers loaded thereon; and measuring temperatures of the low resistance silicon wafers by detecting infrared rays radiated from surfaces of the respective low resistance silicon wafers while the rotary table is rotated.

According to yet another embodiment of the present disclosure, there is provided a heat processing apparatus wherein a plurality of substrates are loaded on a surface of a rotary table installed in a processing vessel and a heat process is performed on the plurality of substrates while rotating the rotary table. The heat processing apparatus includes a control part configured to perform the following steps in the following order: loading a plurality of low resistance silicon wafers haying a resistivity of 0.02 Ω·cm or less at room temperature (20 degrees C.) on the surface of the rotary table; rotating the rotary table having the plurality of low resistance silicon wafers loaded thereon; and measuring temperatures of the low resistance silicon wafer by detecting infrared rays radiated from surfaces of the respective low resistance silicon wafers while the rotary table is rotated.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic longitudinal cross sectional view of a heat processing apparatus according to a first embodiment.

FIG. 2 is a schematic perspective view of the heat processing apparatus according to the first embodiment.

FIG. 3 is a schematic plan view of the heat processing apparatus according to the first embodiment.

FIG. 4 is a partial cross sectional view illustrating a temperature measurement part in the heat processing apparatus according to the first embodiment.

FIGS. 5A to 5C are views illustrating an operation of a radiation temperature measurement part.

FIG. 6 is a view illustrating a relationship between a rotary table and a temperature measurement region.

FIG. 7 is a schematic longitudinal cross sectional view of a heat processing apparatus according to a second embodiment.

FIG. 8 is a schematic longitudinal cross sectional view illustrating an example of a heat processing apparatus according to a third embodiment.

FIG. 9 is a schematic longitudinal cross sectional view illustrating another example of a heat processing apparatus according to the third embodiment.

FIG. 10 is a schematic longitudinal cross sectional view of a heat processing apparatus according to a fourth embodiment.

FIG. 11 is a schematic longitudinal cross sectional view of a heat processing apparatus according to a fifth embodiment.

FIG. 12 is a graph showing a relationship between a position in a diameter direction and a temperature of a rotary table in Example 1.

FIG. 13 is a graph showing a relationship between a position in a diameter direction and a temperature of a rotary table in Example 2.

FIG. 14 is a graph showing a relationship between a position in a diameter direction and a temperature of a rotary table in Example 3.

FIG. 15 is a graph showing a relationship between a position in a diameter direction and a temperature of a rotary table in Example 4.

FIG. 16 is a graph showing a relationship between a position in a diameter direction and a temperature of a rotary table in Comparative Example 1.

FIG. 17 is a graph showing a relationship between a position in a diameter direction and a temperature of a rotary table in Comparative Example 2.

### DETAILED DESCRIPTION

Hereinafter, embodiments of the present disclosure will be described with reference to the accompanying drawings. Further, in the specification and the drawings, components having substantially like functions will be assigned like reference numerals, and redundant description will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A temperature measuring method of an embodiment of the present disclosure is a temperature measuring method for measuring a temperature in a processing vessel of a semiconductor manufacturing apparatus by means of a radiation temperature measurement part configured to measure a temperature by detecting infrared rays radiated from an object, wherein a low resistance silicon wafer having a resistivity of 0.02 Ω·cm or less at room temperature (20 degrees C.) is used as an object of which the temperature is to be measured by the radiation temperature measurement part. With this configuration, a temperature in the processing vessel can be measured with high precision even in a low temperature region (for example, in a range of 200 degrees C. to 400 degrees C.). Further, for low resistance silicon wafers, since an emissivity deviation between the wafers is small, a temperature in the processing vessel can be measured with high precision even when the wafers are different from each other in manufacturing history.

Hereinafter, an example is illustrated in which temperature measuring methods of the embodiments are applied to a heat processing apparatus as an example of a semiconductor manufacturing apparatus. However, the present disclosure is not limited thereto, and can be applied to other various semiconductor manufacturing apparatuses.

### First Embodiment

In the first embodiment, a temperature measuring method in a semi-batch type heat processing apparatus will be described. In the semi-batch type heat processing apparatus, a film is formed on a plurality of wafers loaded on a rotary table, which is installed in a processing vessel, in its rotational direction, by supplying a plurality of reaction gases reacted with each other to the wafers.

### (Configuration of Heat Processing Apparatus)

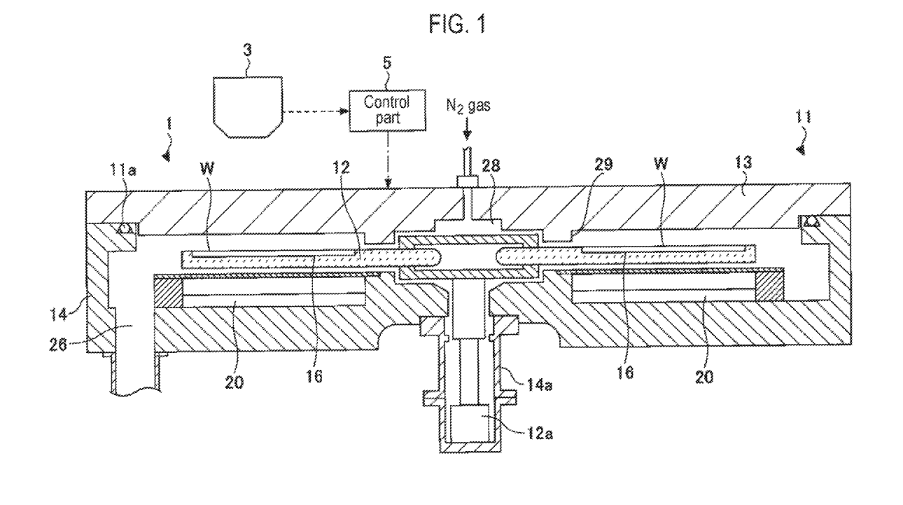

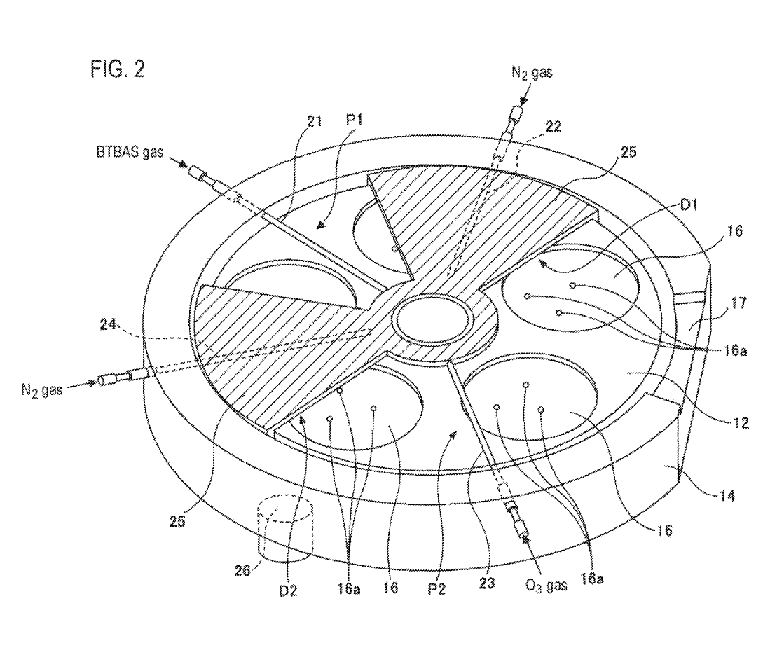

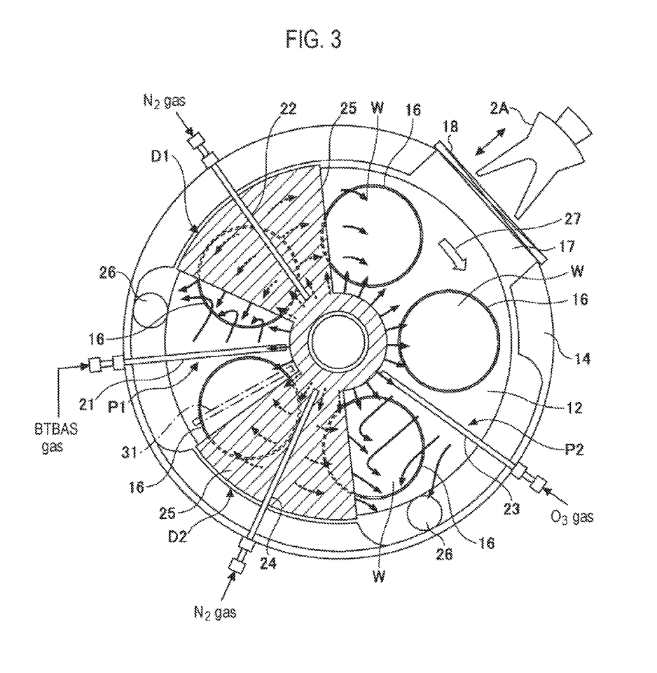

FIG. 1 is a schematic longitudinal cross sectional view of a heat processing apparatus according to a first embodiment. FIG. 2 is a schematic perspective view of the heat processing apparatus according to the first embodiment. FIG. 3 is a schematic plan view of the heat processing apparatus according to the first embodiment.

A heat processing apparatus 1 of the embodiment includes a flat processing vessel 11 having a substantially cylindrical shape and a disk-shaped rotary table 12 horizontally installed in the processing vessel 11. The processing vessel 11 is installed in an air atmosphere, and includes a ceiling plate 13 and a vessel main body 14 forming a sidewall and a bottom portion of the processing vessel 11. In FIG. 1, reference numeral 11a designates a sealing member for air-tightly maintaining the inside of the processing vessel 11, and reference numeral 14a designates a cover blocking a central portion of the vessel main body 14. In FIG. 1, reference numeral 12a is a rotary drive mechanism, and the rotary drive mechanism 12a rotates the rotary table 12 in its circumferential direction.

Five concave portions 16 are formed in a surface of the rotary table 12 along a rotational direction of the rotary table 12. In the drawings, reference numeral 17 designates a transfer port. In FIG. 3, reference numeral 18 designates a shutter (not shown in FIG. 2) capable of opening/closing the transfer port 17. If a transfer mechanism 2A enters the processing vessel 11 from the transfer port 17 while holding a wafer W, lifting pins (not shown) protrude from the rotary table 12 through holes 16a of the concave portion 16 at positions facing the transfer port 17 to lift up the wafer W. The wafer W is delivered between the concave portion 16 and the transfer mechanism 2A.

A series of operations performed by the transfer mechanism 2A, the lifting pins, and the rotary table 12 are repeated, so that wafers W are delivered to the respective concave portions 16. When a wafer W is taken out of the processing vessel 11, the lifting pins lift up the wafer W disposed in the concave portion 16. The transfer mechanism 2A receives the wafer W lifted up by the lifting pins and transfers the wafer W outside the processing vessel 11.

A first reaction gas nozzle 21, a separation gas nozzle 22, a second reaction gas nozzle 23, and a separation gas nozzle 24, each of which extends in a rod shape toward the center from the outer periphery of the rotary table 12, are arranged in this order in the circumferential direction on the rotary table 12. Each of the gas nozzles 21 to 24 includes openings at a lower portion thereof, and supplies a gas along the diameter of the rotary table 12. The first reaction gas nozzle 21 ejects bis(tertiary-butylamino) silane (BTBAS) gas and the second reaction gas nozzle 23 ejects O₃ (ozone) gas. The separation gas nozzles 22 and 24 eject N₂ (nitrogen) gas.

The ceiling plate 13 of the processing vessel 11 includes two fan-shaped protrusion portions 25 protruding downward, and the protrusion portions 25 are formed at intervals in the circumferential direction. Each of the separation gas nozzles 22 and 24 is installed so as to be deeply embedded into the protrusion portion 25 and divide the protrusion portion 25 in the circumferential direction. The first reaction gas nozzle 21 and the second reaction gas nozzle 23 are installed to be spaced apart from the protrusion portions 25, respectively.

If a wafer W is loaded in each of the concave portions 16, exhaust is passed through exhaust ports 26 opened in the bottom of the vessel main body 14 at positions in the diameter direction of the rotary table 12 further out than a region between separation regions D1 and D2 under the protrusion portions 25. Thus, the atmosphere of the processing vessel 11 becomes a vacuum atmosphere. In addition, as the rotary table 12 is rotated, the wafer W is heated, for example, to 760 degrees C., through the rotary table 12 by a heater 20 installed below the rotary table 12. In FIG. 3, an arrow 27 indicates a rotational direction of the rotary table 12.

Subsequently, gases are supplied from the respective gas nozzles 21 to 24, and the wafer W alternately passes through a first processing region P1 under the first reaction gas nozzle 21 and a second processing region P2 under the second reaction gas nozzle 23. Accordingly, the BTBAS gas is adsorbed onto the water W, and the O₃ gas is subsequently adsorbed onto the wafer W so that BTBAS molecules are oxidized, thereby forming a molecular layer of silicon oxide as a single layer or plural layers. Thus, the molecular layers of silicon oxide are sequentially laminated, thereby forming a silicon oxide film having a predetermined film thickness.

In this film forming process, the N₂ gas supplied to the separation regions D1 and D2 from the separation gas nozzles 22 and 24 spreads in the circumferential direction in the separation regions D1 and D2, thereby preventing the BTBAS gas and the O₃ gas from being mixed together on the rotary table 12. In addition, surplus BTBAS gas and O₃ gas are allowed to flow into the exhaust ports 26. Furthermore, in this film forming process, the N₂ gas is supplied into a space 28 in a central region of the rotary table 12. The gas passes below a ring-shaped protruding portion 29 protruding downward from the ceiling plate 13 and is supplied outward in the diameter direction of the rotary table 12, thereby preventing the BTBAS gas and the O₃ gas from being mixed together in the central region C. In FIG. 3, flows of the respective gases in the film forming process are shown by arrows. Although not shown in FIG. 3, the N₂ gas is also supplied into the cover 14a and onto a back side of the rotary table 12, so that the reaction gases are purged.

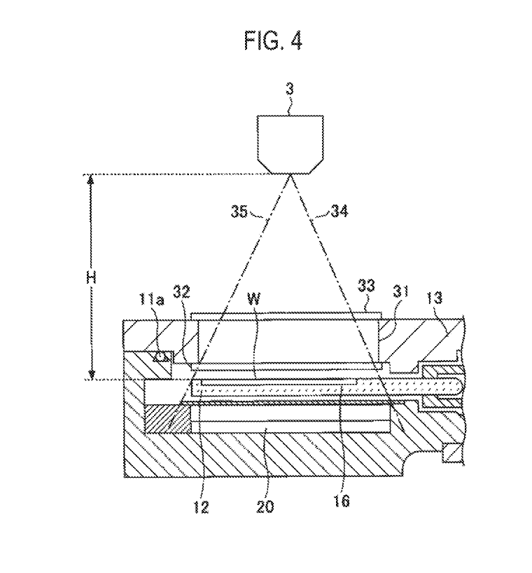

Subsequently, the heat processing apparatus according to the embodiment will be described with reference to FIG. 4 which shows an enlarged longitudinal cross section of the ceiling plate 13 and the rotary table 12. FIG. 4 is a partial cross sectional view illustrating a temperature measurement part in the heat processing apparatus according to the first embodiment. Specifically, FIG. 4 shows a cross section between the first processing region P1 in which the first reaction gas nozzle 21 is installed and the separation region D2 adjacent to an upstream side of the first processing region P1 in the rotational direction.

A slit 31 extending in the diameter direction of the rotary table 12 is opened at a position indicated by a chain line in FIG. 3 in the ceiling plate 13, and a lower window 32 and an upper window 33 are provided to cover the top and the bottom of the slit 31. The lower window 32 and the upper window 33 are made of, for example, sapphire to allow the infrared rays radiated from a surface of the rotary table 12 to transmit therethrough, so that a temperature can be measured by a radiation temperature measurement part 3 which will be described later. The surface of the rotary table 12 also includes a surface of the wafer W.

The radiation temperature measurement part 3, as an example of a noncontact type thermometer, is installed above the slit 31. In FIG. 4, the height H from the surface of the rotary table 12 to the bottom end of the radiation temperature measurement part 3 is, for example, 500 mm. The radiation temperature measurement part 3 guides the infrared rays radiated from a temperature measurement region of the rotary table 12 to a detection part 301 which will be described later, so that the detection part 301 acquires a temperature measurement value corresponding to the amount of the infrared rays. Therefore, this temperature measurement value varies depending on a temperature of a place where the temperature measurement value is acquired. The acquired temperature measurement value is transmitted to a control part 5 which will be described later.

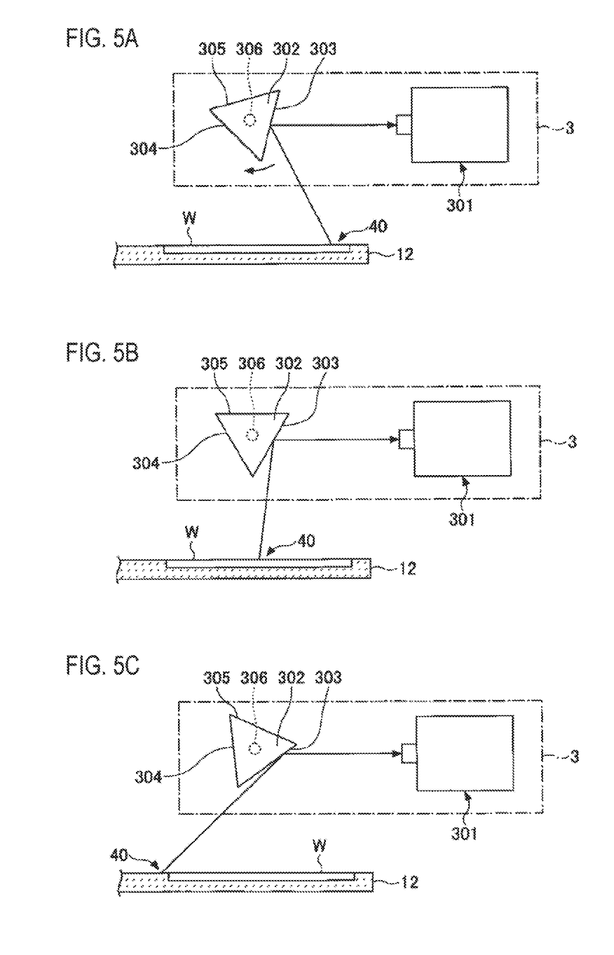

Then, the radiation temperature measurement part 3 will be described with reference to FIGS. 5A to 5C. FIGS. 5A to 5C are views illustrating an operation of a radiation temperature measurement part.

As shown in FIGS. 5A to 5C, the radiation temperature measurement part 3 includes a rotating body 302 including a servomotor that rotates at 50 Hz. The rotating body 302 is formed in a triangular shape from a plan view, and three side surfaces of the rotating body 302 are configured as reflective surfaces 303 to 305, respectively. As shown in FIGS. 5A to 5C, the rotating body 302 rotates about a rotating shaft 306, so that the infrared rays of a temperature measurement region 40 on the rotary table 12 including a wafer W are reflected from any one of the reflective surfaces 303 to 305 as indicated by an arrow in FIGS. 5A to 5C and is guided to the detection part 301. The scanning is performed by moving the position of the temperature measurement region 40 in the diameter direction of the rotary table 12.

The detection part 301 is configured to repeatedly introduce infrared rays a predetermined number of times (e.g., 128 times) from one reflective surface, thereby detecting temperatures at a predetermined number of places (e.g., 128 places) the diameter direction of the rotary table 12. The reflective surfaces 303 to 305 are sequentially positioned on an optical path of the infrared rays as the rotating body 302 rotates, so that the scanning can be repeatedly performed from the inner side to the outer side of the rotary table. The scanning rate is 150 Hz. That is, the radiation temperature measurement part 3 may perform the scanning 150 times for one second. The temperature measurement region 40 is a spot having a diameter of 5 mm. The scanning is performed in a range from an inner position of the rotary table 12 than the concave portion 16 in which the wafer W is loaded to an outer peripheral end of the rotary table 12. In FIG. 4, chain lines 34 and 35 indicate the infrared rays toward the radiation temperature measurement part 3 from the temperature measurement regions 40 moving to the innermost and outermost peripheral sides of the rotary table 12, respectively.

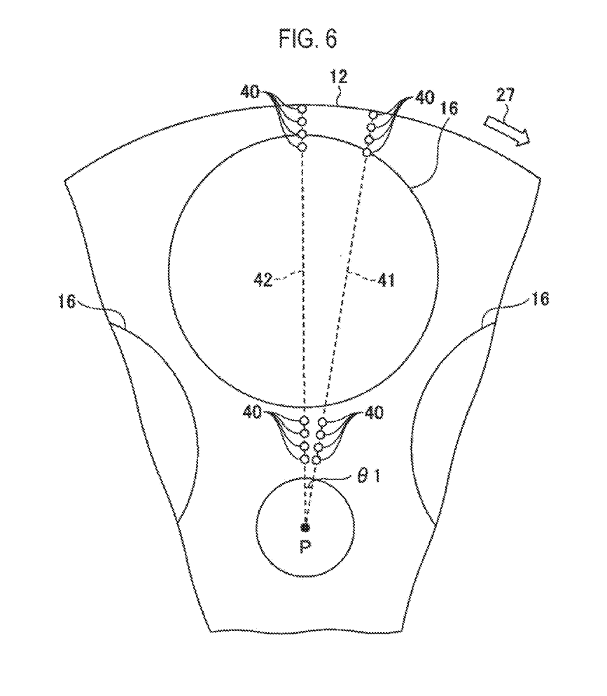

The scanning by the radiation temperature measurement part 3 is performed in the state in which the rotary table 12 is rotated. The rotational speed of the rotary table 12 is 240 rpm in this example. FIG. 6 is a plan view illustrating a relationship between the rotary table 12 and the temperature measurement region 40. In FIG. 6, reference numeral 41 designates a column (scan line) of the temperature measurement region 40 when an n-th (n is an integer) scanning is performed from the inner side to the outer side of the rotary table 12 in the state in which the rotary table 12 is rotated. In FIG. 6, reference numeral 42 designates a scan line when an (n+1)-th (n is an integer) scanning is performed. As the rotary table 12 is rotated, a central angle between the scan lines 41 and 42 with respect to the rotational center P of the rotary table 12 forms an angle θ1 according to the rotational speed of the rotary table 12. The scanning is repeated while the rotary table 12 is rotated as described above, so that temperature measurement values at a plurality of positions on the rotary table 12 are sequentially acquired.

In addition, the heat processing apparatus 1 is provided with the control part 5 constituted by a computer for control of the entire operation of the apparatus. A program for performing the temperature measurement which will be described below is stored in a memory of the control part 5. This program includes a group of steps for performing various kinds of operations of the apparatus, and is installed into the control part 5 from a storage medium, such as a hard disk, compact disk, magneto-optical disk, memory card, or flexible disk.

### (Temperature Measuring Method)

An example of a temperature measuring method in the heat processing apparatus 1 according to an embodiment of the present disclosure will be described.

The temperature measuring method of the present embodiment, which is a temperature measuring method in the above-described heat processing apparatus, includes the steps of: loading a plurality of low resistance silicon wafers having a resistivity of 0.02 Ω·cm or less at room temperature (20 degrees C.) on the surface of the rotary table, rotating the rotary table having the plurality of low resistance silicon wafers loaded thereon, and measuring temperatures of the low resistance silicon wafers by detecting infrared rays radiated from a surface of each of the plurality of low resistance silicon wafers while the rotary table is rotated.

Hereinafter, each of the steps will be described.

In the loading step, a plurality of low resistance silicon wafers having a resistivity of 0.02 Ω·cm or less at room temperature are loaded on the rotary table 12.

Specifically, first, the shutter 18 installed in the transfer port 17 is opened, and a low resistance silicon wafer is delivered to the concave portion 16 of the rotary table 12 through the transfer port 17 by the transfer mechanism 2A from outside of the processing vessel 11. The delivery is performed as the lifting pins (not shown) are moved up and down through through-holes in the bottom surface of the concave portion 16 from a lower portion of the processing vessel 11 when the concave portion 16 stops at a position facing the transfer port 17. The delivery of this low resistance silicon wafer is performed while intermittently rotating the rotary table 12, so that low resistance silicon wafers are loaded in five concave portions 16 of the rotary table 12, respectively.

In the rotating step, the rotary table 12 having the plurality of low resistance silicon wafers loaded thereon is rotated.

Specifically, after the low resistance silicon wafers are respectively loaded on the five concave portions 16 of the rotary table 12, the shutter 18 is closed, and the processing vessel 11 is allowed to be in a vacuum state using a vacuum pump (not shown) connected to the exhaust ports 26. Subsequently, the N₂ gas as a separation gas is ejected from the separation gas nozzles 22 and 24 at a predetermined flow rate, and the N₂ gas is supplied into the space 28 in the central region of the rotary table 12 at the predetermined flow rate. Accordingly, the pressure in the processing vessel 11 is adjusted to a preset pressure (for example, the same pressure at which the wafers W are heat processed) by a pressure adjusting means (not shown) connected to the exhaust ports 26. Subsequently, the low resistance silicon wafers are heated, for example, to a predetermined temperature (e.g., 760 degrees C.) by the heater 20 while the rotary table 12 is rotated clockwise.

In the measuring step, a temperature of the low resistance silicon wafer is measured by detecting the infrared rays radiated from a surface of each of the plurality of low resistance silicon wafers while the rotary table 12 is rotated.

Specifically, in the state in which the rotatable 12 is rotated, infrared rays of the temperature measurement region 40 in the rotary table 12 including the low resistance silicon waters are reflected from any one of the reflective surfaces 303 to 305 and guided to the detection part 301 by rotating the rotating body 302 of the radiation temperature measurement part 3 about the rotating shaft 306, and the scanning is performed by moving the position of the temperature measurement region 40 in the diameter direction of the rotary table 12. At this time, the detection part 301 consecutively introduces the infrared rays a predetermined number of times (e.g., 128 times) from one reflective surface, thereby detecting temperatures at a predetermined number of places (e.g., 128 places) along the diameter direction of the rotary table 12. As described above, the infrared rays radiated from the surface of each of the plurality of low resistance silicon waters loaded on the rotary table 12 are detected by repeating the scanning by the radiation temperature measurement part 3 while rotating the rotary table 12, thereby sequentially measuring temperatures of the plurality of low resistance silicon wafers.

Furthermore, while it has been described in the first embodiment that the radiation temperature measurement part 3 is configured to move and scan the position of the temperature measurement region 40 in the diameter direction of the rotary table 12 to measure the temperatures, the present disclosure is not limited thereto. For example, the radiation temperature measurement part 3 may be configured to measure a temperature at an arbitrary point in the diameter direction of the rotary table 12 while not moving the position of the temperature measurement region 40 in the diameter direction of the rotary table 12. In addition, a well-known infrared ray radiation thermometer, or a thermal image measuring device (thermography) may be used as the radiation temperature measurement part 3.

### Second Embodiment

In the second embodiment, a temperature measuring method in a batch type heat processing apparatus, in which one batch is configured by multiple sheets of wafers loaded in a wafer boat and a film forming process is performed on a batch basis in a processing vessel, will be described.

(Configuration of Heat processing Apparatus)

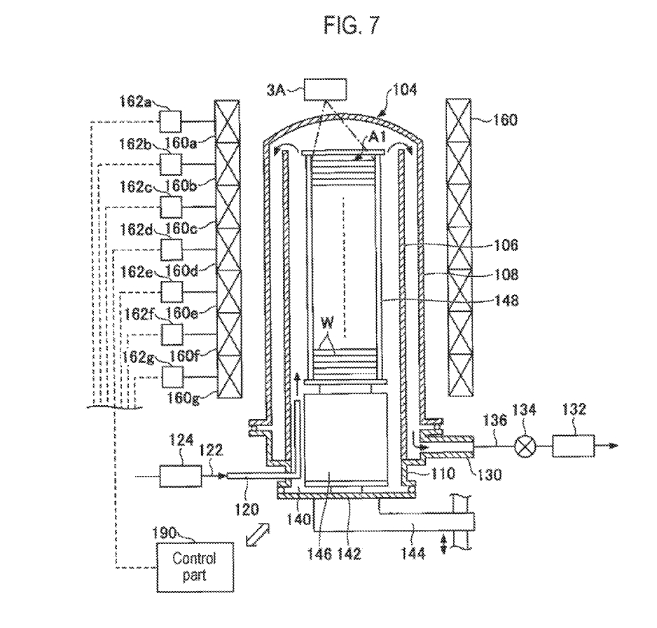

FIG. 7 is a schematic longitudinal cross sectional view of the heat processing apparatus according to the second embodiment.

As shown in FIG. 7, the heat processing apparatus of the second embodiment includes a processing vessel 104 having a substantially cylindrical shape of which the length direction is vertical. The processing vessel 104 has a double-tube structure constituted by a cylindrical inner tube 106 and an outer tube 108 having a ceiling and concentrically disposed outside of the inner tube 106. The inner tube 106 and the outer tube 108 are formed of, for example, a heat resistant material such as quartz.

The lower ends of the inner and outer tubes 106 and 108 are supported by a manifold 110 made of stainless steel or the like. The manifold 110 is fixed to, for example, a base plate not shown. Since the manifold 110 together with the inner tube 106 and the outer tube 108 defines a substantially cylindrical internal space, the manifold 110 is configured as a portion of the processing vessel 104. That is, the processing vessel 104 includes th tube 106 and the outer tube 108 made of a heat resistant material, for example, quartz or the like, and the manifold 110 made of stainless steel or the like, and the manifold 110 is installed at a lateral side of a lower portion of the processing vessel 104 so as to support the inner tube 106 and the outer tube 108 from below.

The manifold 110 has a gas introduction portion 120 which introduces a variety of gases, such as processing gases such as a film forming gas and an additive gas used in a film forming process, and a purge gas used in a purging process, into the processing vessel 104. While FIG. 7 shows a case in which one gas introduction portion 120 is formed, the present disclosure is not limited thereto, and a plurality of gas introduction portions 120 may be formed according to the types of gases used and the like.

The type of the processing gas is not specifically limited and may be appropriately selected according to the type of a film to be formed. The type of the purge gas is not specifically limited and may include, for example, an inert gas such as nitrogen (N₂) gas.

An introduction pipe 122 for introducing a variety of gases into the processing vessel 104 is connected to the gas introduction portion 120. In addition, a flow rate adjuster 124 such as a mass flow controller, a valve not shown, or the like for adjusting a gas flow rate is installed in the introduction pipe 122.

The manifold 110 has a gas exhaust part 130 for exhausting the interior of the processing vessel 104. An exhaust pipe 136, which includes a vacuum pump 132, an opening degree variable valve 134, and the like, for controlling depressurization of the interior of the processing vessel 104, is connected to the gas exhaust part 130.

A furnace port 140 is formed in a lower end of the manifold 110. The furnace port 140 is provided with a circular disk shaped lid 142 made of for example, stainless steel or the like. The lid 142 is installed to be elevatable by, for example, a lifting mechanism 144 functioning as a boat elevator, and is configured to air-tightly seal the furnace port 140.

A thermal insulation container 146 made of, for example, quartz, is installed above the lid 142. A wafer boat 148 made of, for example, quartz, for horizontally holding, for example, 50 to 175 sheets of wafers W in multiple stages at predetermined intervals is loaded above the thermal insulation container 146. The wafer boat 148 is configured to be rotatable through the thermal insulation container 146 by a not shown rotating mechanism installed at the lid 142.

The wafer boat 148 is carried into the processing vessel 104 by moving up the lid 142 using the lifting mechanism 144, and various film forming processes are performed on the wafers W held in the wafer boat 148. After the various film forming processes are performed, the wafer boat 148 is carried out of the processing vessel 104 to a loading area below the processing vessel 104 by moving down the lid 142 using the lifting mechanism 144. The multiple sheets of wafers W loaded in the wafer boat 148 constitute one batch, and the various film forming processes are performed on a batch basis.

A heater 160, which has a cylindrical shape, for example, and is capable of heat controlling the processing vessel 104 to a predetermined temperature, is installed at an outer peripheral side of the processing vessel 104. The heater 160 is divided into seven zones, and heaters 160a to 160g are installed from top to bottom in the vertical direction. The heaters 160a to 160g are configured to have heat generating amounts controlled independently by power controllers 162a to 162g, respectively. In addition, temperature sensors not shown are installed in an inner wall of the inner tube 106 and/or an outer wall of the outer tube 108 corresponding to the heaters 160a to 160g. While FIG. 7 shows a case in which the heater 160 is divided into the seven zones, the number of zones into which the heater 160 is divided is not limited thereto and may be, for example six or less, or eight or more. Alternatively, the heater 160 may not be divided into a plurality of zones.

A radiation temperature measurement part 3A, as an example of a noncontact type thermometer, is installed above the processing vessel 104. The radiation temperature measurement part 3A measures a temperature of a resistance silicon wafer held in the wafer boat 148 by detecting infrared rays radiated from the low resistance silicon wafer. The radiation temperature measurement part 3A may have, for example, the same configuration as the radiation temperature measurement part 3 described in the first embodiment, or may be a well-known infrared ray radiation thermometer a thermography.

The heat processing apparatus is provided with the control part 190 constituted by a computer for controlling the entire operation of the apparatus. A program for performing the temperature measurement is stored in a memory of the control part 190. The program includes a group of steps for performing various kinds of operations of the apparatus, and is installed into the control part 190 from a storage medium, such as a hard disk, compact disk, magneto-optical disk, memory card, or flexible disk.

The control part 190 may feedback control the heater 160 based on the temperature of the low resistance silicon wafer measured by the radiation temperature measurement part 3A. When a difference between the temperature at the position where the low resistance silicon wafer is installed and the temperature within the processing vessel 104 is large, the control part 190 corrects the temperature of the low resistance silicon wafer, and feedback controls the heater 160 based on the corrected temperature.

### (Temperature Measuring Method)

An example of a temperature measuring method in the heat processing apparatus according to the second embodiment will be described.

The temperature measuring method of the second embodiment is a temperature measuring method in the above-described heat processing apparatus and includes a loading step, a carrying-in step, a rotating step, and a measuring step.

Hereinafter, each of the steps will be described.

In the loading step, a low resistance silicon wafer having a resistivity of 0.02 Ω·cm or less at room temperature (20 degrees C.) is loaded in the wafer boat 148. In some embodiments, the position at which the low resistance silicon wafer is loaded in the wafer boat 148 may be the uppermost end of the wafer boat 148 (position A1 in FIG. 7). With this configuration, even in a state where a product wafer, a dummy wafer or the like is held in another position in the wafer boat 148, the infrared rays radiated from the low resistance silicon wafer can be detected by the radiation temperature measurement part 3A. The low resistance silicon wafer may be loaded in other positions as long as the radiation temperature measurement part 3A can detect the infrared rays radiated from the low resistance silicon wafer.

In the carrying-in step, the wafer boat 148 having the low resistance silicon wafer loaded therein is carried in the processing vessel 104.

In the rotating step, the wafer boat 148 carried in the processing vessel 104 is rotated by the rotating mechanism, and the low resistance silicon wafer is heated to a predetermined temperature by the heater 160.

In the measuring step, in the state where the wafer boat 148 is rotated, the infrared rays radiated from a surface of the low resistance silicon wafer are detected by the radiation temperature measurement part 3A, thereby measuring the temperature of the low resistance silicon wafer.

### Third Embodiment

In the third embodiment, another example of a temperature measuring method for measuring a temperature within a processing vessel in a batch type heat processing apparatus, in which one batch is configured by multiple sheets of wafers loaded in a wafer boat and a film forming process is performed on a batch basis in the processing vessel, will be described.

The heat processing apparatus of the third embodiment is different from the heat processing apparatus of the second embodiment in that a radiation temperature measurement part is installed below the processing vessel. Other configurations are the same as those of the heat processing apparatus of the second embodiment.

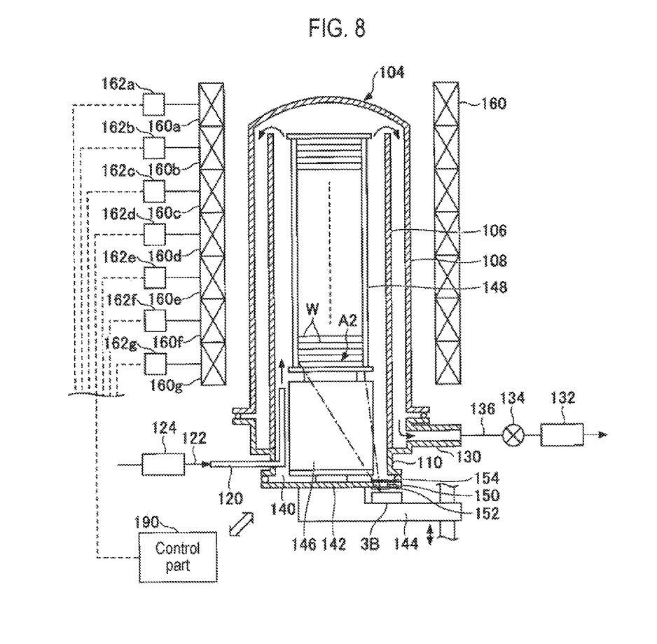

FIG. 8 is a schematic longitudinal cross sectional view illustrating an example of a heat processing apparatus according to the third embodiment.

As shown in FIG. 8, a radiation temperature measurement part 3B is installed below the processing vessel 104, for example, in an upper surface of the lifting mechanism 144. A slit 150 is opened in the lid 142 at a position corresponding to the position where the radiation temperature measurement part 3B is installed, and a lower window 152 and an upper window 154 are installed in the lid 142 so as to cover the top and bottom of the slit 150. The lower window 152 and the upper window 154 are made of, for example, sapphire, so that they transmit the infrared rays radiated from the surface of the low resistance silicon wafer and the radiation temperature measurement part 3B can measure the temperature.

When the radiation temperature measurement part 3B is installed below the processing vessel 104 in the same manner as this embodiment, the loading position of the low resistance silicon wafer may be at the lowermost end of the wafer boat 148 (position A2 in FIG. 8). With this configuration, even in a state where a product wafer, a dummy water or the like is held in another position in the wafer boat 148, the infrared rays radiated from the low resistance silicon wafer can be detected by the radiation temperature measurement part 3B. The low resistance silicon wafer may be loaded in other positions as long as the radiation temperature measurement part 3B can detect the infrared rays radiated from the low resistance silicon wafer.

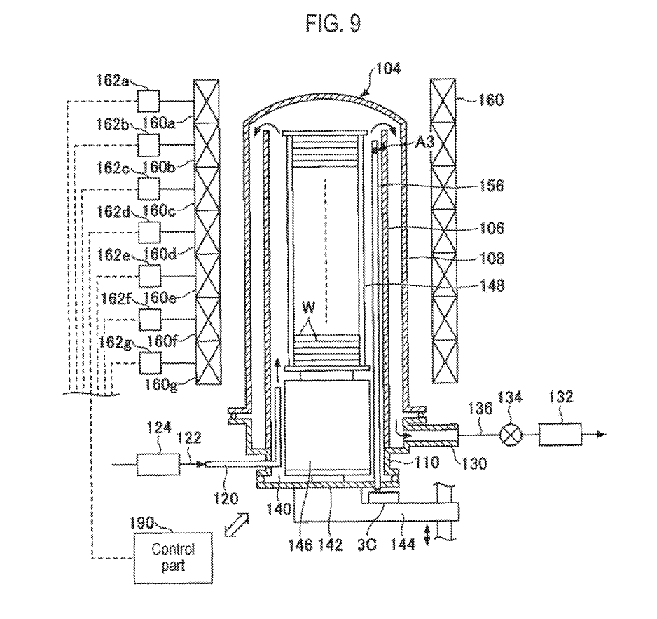

FIG. 9 is a schematic longitudinal cross sectional view illustrating another example of a heat processing apparatus according to the third embodiment.

As shown in FIG. 9, a radiation temperature measurement part 3C is installed below the processing vessel 104, for example, on an upper surface of the lifting mechanism 144. A pipe-shaped member 156, which penetrates the lid 142 from the bottom of the lid 142 to be inserted into the processing vessel 104 and has a leading end disposed at an outer peripheral side of the wafer boat 148, is installed above the radiation temperature measurement part 3C. The pipe-shaped member 156 functions as a transmission line for transmitting infrared rays.

When the radiation temperature measurement part 3C is installed below the processing vessel 104 and the pipe-shaped member 156 is installed in the same manner as this embodiment, the loading position of the low resistance silicon wafer may be in the interior of the pipe-shaped member 156 near the leading end of the pipe-shaped member 156 (position A3 in FIG. 9). At this time, the low resistance silicon wafer is processed to have a size capable of being accommodated in the pipe-shaped member 156 and installed in the interior of the pipe-shaped member 156 at the leading end of the pipe-shaped member 156. In addition, a plurality of pipe-shaped members 156 may be installed, and a plurality of radiation temperature measurement parts 3C may be installed corresponding to the plurality of pipe-shaped members 156, respectively. In this case, leading ends of the pipe-shaped member 156 may have different positions from one another in the vertical direction. With this configuration, temperatures at different positions from one another in the vertical direction can be measured.

### Fourth Embodiment

In the fourth embodiment, other example of a temperature measuring method for measuring a temperature within a processing vessel in a batch type heat processing apparatus, in which one batch is configured by multiple sheets of wafers loaded in a wafer boat and a film forming process is performed on a batch basis in the processing vessel, will be described.

The heat processing apparatus of the fourth embodiment is different from the heat processing apparatus of the second embodiment in that a radiation temperature measurement part is installed at a lateral side of the processing vessel. Other configurations are the same as those of the heat processing apparatus of the second embodiment.

FIG. 10 is a schematic longitudinal cross sectional view of the heat processing apparatus according to a fourth embodiment.

As shown in FIG. 10, radiation temperature measurement parts 3D is installed at a lateral side of the processing vessel 104. Specifically, a plurality of radiation temperature measurement parts 3D-a to 3D-g penetrate the heaters 160a to 160g from outside the heaters 160a to 160g and are inserted toward the processing vessel 104, respectively, and leading ends (temperature detection parts) thereof are disposed in the vicinity of the outer wall of the outer tube 108. Alternatively, the number of the radiation temperature measurement parts 3D may be one.

When the leading end of the radiation temperature measurement part 3D is disposed in the vicinity of the outer wall of the outer tube 108 in the same manner as this embodiment, the loading position of the low resistance silicon wafer may be a position in the outer wall of the outer tube 108 corresponding to the installation position of the radiation temperature measurement part 3D. That is, as shown in FIG. 10, the low resistance silicon wafers are installed at positions A4-a to A4-g corresponding to the installation positions of the radiation temperature measurement parts 3D-a to 3D-g. With this configuration, temperatures at different positions from one another in the vertical direction can be measured. A method of installing the low resistance silicon water in the outer wall of the outer tube 108 is not specifically limited, and may be installed in the outer wall of the outer tube 108, for example, while being held in a holder. The loading position of the low resistance silicon wafer may be a position in the wafer boat 148 corresponding to the installation position of the radiation temperature measurement part 3D.

### Fifth Embodiment

In the fifth embodiment, another example of a temperature measuring method for measuring a temperature within a processing vessel in a batch type heat processing apparatus, in which one batch is configured by multiple sheets of wafers loaded in a wafer boat and a film forming process is performed on a batch basis in the processing vessel, will be described.

The heat processing apparatus of the fifth embodiment is different from the heat processing apparatus of the second embodiment in that the leading end (temperature detector) of the radiation temperature measurement part is installed inside of the processing vessel. Other configurations are the same as those of the heat processing apparatus of the second embodiment.

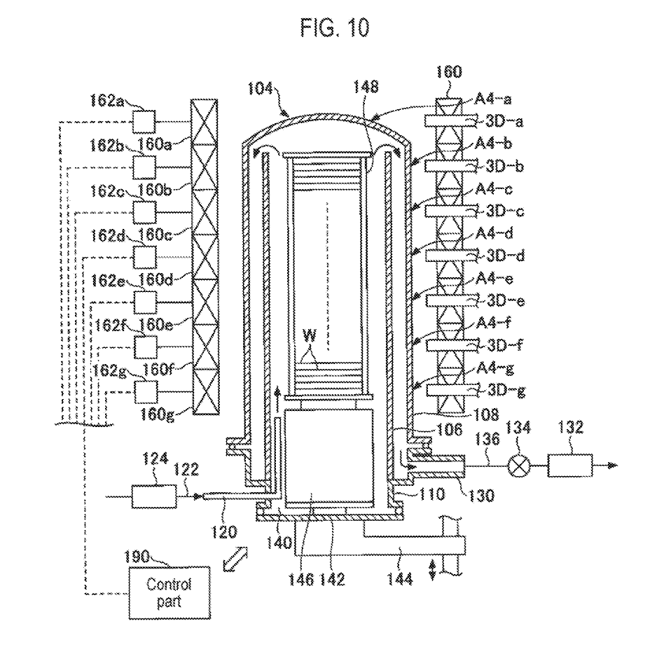

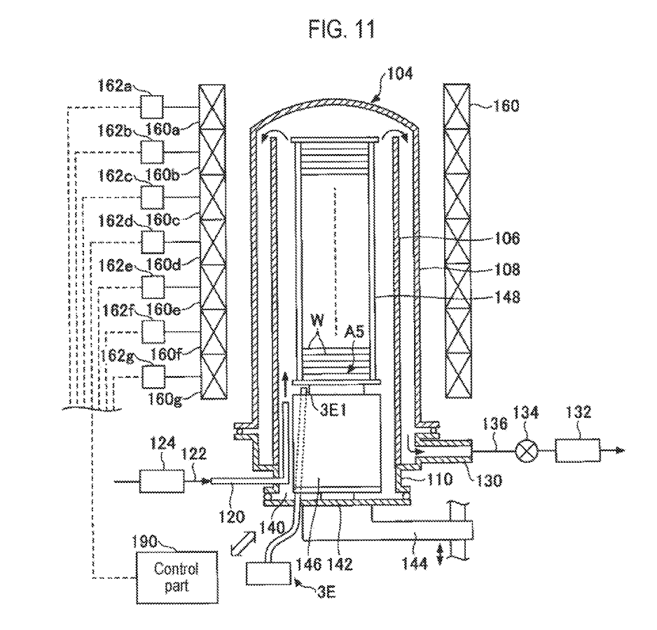

FIG. 11 is a schematic longitudinal cross sectional view of the heat processing apparatus according to a fifth embodiment.

As shown in FIG. 11, a leading end of a radiation temperature measurement part 3E is installed inside of the processing vessel 104. Specifically, a radiation temperature measurement part 3E has an optical fiber part 3E1, which penetrates the lid 142 from the bottom of the lid 142 to be inserted into the processing vessel 104 and has a leading end disposed at a position near the lowermost end of the wafer boat 148. The radiation temperature measurement part 3E is configured to detect infrared rays incident from the leading end of the optical fiber part 3E1.

When the leading end of the radiation temperature measurement part 3E is disposed at the position near the lowermost end of the wafer boat 148 in the same manner as this embodiment, the loading position of the low resistance silicon water may be the lowermost end of the water boat 148 (position A5 in FIG. 10).

### EXAMPLES

Hereinafter, the present disclosure will be specifically described in Examples, but the present disclosure is not interpreted as being limited to these Examples.

### Example 1

In Example 1, the temperature measurement was performed by the temperature measuring method of the above-described first embodiment. Example 1 employed the rotary table 12 having six concave portions 16, i.e., Slot2, Slot3, Slot4, Slot5, and Slot6, formed along the rotational direction of the rotary table 12.

First, a low resistance silicon wafer was loaded in each of the six concave portions 16 of the rotary table 12. In Example 1, six sheets of P-type silicon wafers doped with B (boron) as impurities and having a resistivity of less than 0.02. Ω·cm at room temperature were employed as the low resistance silicon wafers. In addition, the six sheets of silicon wafers used were manufactured from different ingots from one another.

Subsequently, while rotating the rotary table 12 having the plurality of low resistance silicon waters loaded thereon, the low resistance silicon wafers were heated by the heater 20. In Example 1, the low resistance silicon wafers were heated with the temperature of the heater 20 set at 760 degrees C. while rotating the rotary table 12 clockwise at a rotational speed of 20 rpm.

Subsequently, in a state where the temperature in the processing vessel 11 was stable, temperatures of the six sheets of the low resistance silicon wafers were measured by detecting infrared rays radiated from the respective surfaces of the six sheets of the low resistance silicon wafers.

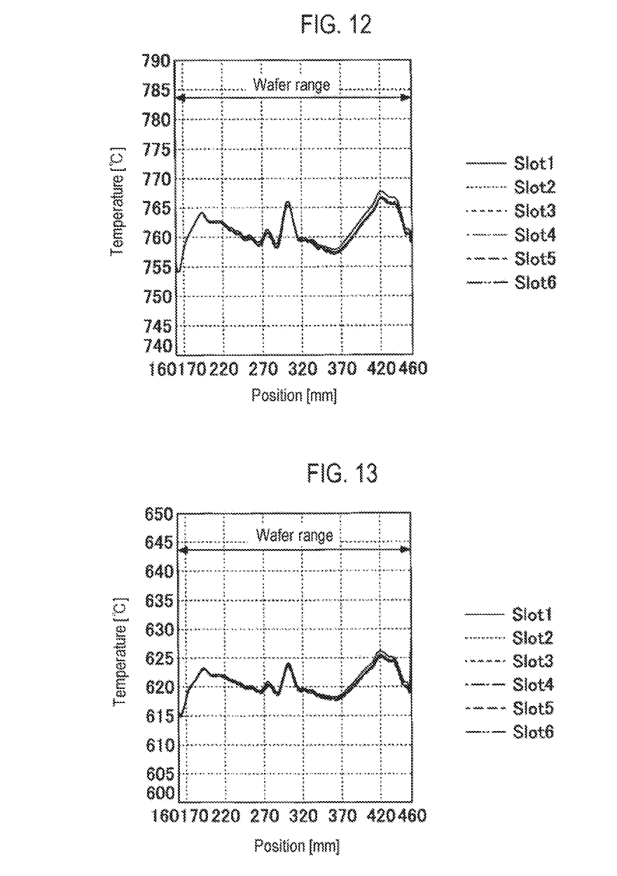

FIG. 12 is a graph showing a relationship between a position in a diameter direction and a temperature of a rotary table in Example 1. In the graph of FIG. 12, the horizontal axis represents the distance (mm) from the rotational center P of the rotary table 12, and the vertical axis represents the temperature (degrees C.). In addition, a range in which the low resistance silicon wafer is loaded (wafer range) is within a distance of 160 mm or more and 460 mm or less from the rotational center P of the rotary table 12.

Specifically, FIG. 12 shows temperature distributions of the six sheets of the low resistance silicon wafers in the diameter direction of the rotary table 12 when the low resistance silicon wafers have been respectively loaded in the six concave portions 16 of the rotary table 12, in FIG. 12, a solid line, a dotted line, a broken line, an alternate long and short dash line, a long dash line, and an alternate long and two short dashes line represent relationships between the temperature and the distance from the rotational center P of the rotary table 12 of the low resistance silicon wafers loaded in Slot1, Slot2, Slot3, Slot4, Slot5, and Slot6, respectively.

As shown in FIG. 12, the six sheets of the low resistance silicon wafers had almost the same temperature at any positions thereof in the diameter direction of the rotary table 12, and a temperature difference at the position where there is the largest temperature difference (the position of about 420 mm in FIG. 12) was 1.2 degrees C.

### Example 2

In Example 2, the temperature measurement was performed by the same temperature measuring method as Example 1 except that the low resistance silicon wafers were heated with the temperature of the heater 20 set at 620 degrees C.

FIG. 13 is a graph showing a relationship between a position in a diameter direction and a temperature of a rotary table in Example 2. In the graph of FIG. 13, the horizontal axis represents the distance (mm) from the rotational center P of the rotary table 12, and the vertical axis represents the temperature (degrees C.). In addition, a range in which the low resistance silicon wafer is loaded is within a distance of 160 mm or more and 460 mm or less from the rotational center P of the rotary table 12.

Specifically, FIG. 13 shows temperature distributions of the six sheets of the low resistance silicon wafers in the diameter direction of the rotary table 12 when the low resistance silicon waters have been respectively loaded in the six concave portions 16 of the rotary table 12. In FIG. 13, a solid line, a dotted line, a broken line, an alternate long and short dash line, a long dash line, and an alternate long and two short dashes line represent relationships between the temperature and the distance from the rotational center P of the rotary table 12 of the low resistance silicon wafers loaded in Slot1, Slot2, Slot3, Slot4, Slot5, and Slot6, respectively.

As shown in FIG. 13, the six sheets of the low resistance silicon wafers had almost the same temperature at any positions thereof in the diameter direction of the rotary table 12, and a temperature difference at the position where there is the largest temperature difference (the position of 420 mm in FIG. 13) was 0.9 degrees C.

### Example 3

In Example 3, the temperature measurement was performed by the same temperature measuring method as Example 1 except that the low resistance silicon wafers were heated with the temperature of the heater 20 set at 155 degrees C.

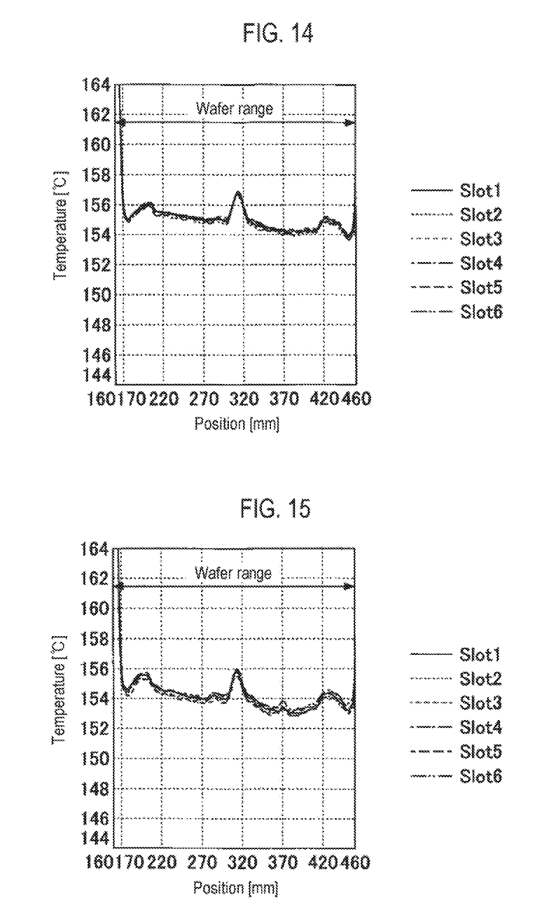

FIG. 14 is a graph showing a relationship between a position in a diameter direction and a temperature of a rotary table in Example 3. In the graph of FIG. 14, the horizontal axis represents the distance (mm) from the rotational center P of the rotary table 12, and the vertical axis represents the temperature (degrees C.). In addition, a range in which the low resistance silicon wafer is loaded is within a distance of 160 mm or more and 460 mm or less from the rotational center P of the rotary table 12.

Specifically, FIG. 14 shows temperature distributions of the six sheets of the low resistance silicon wafers in the diameter direction of the rotary table 12 when the low resistance silicon wafers have been respectively loaded in the six concave portions 16 of the rotary table 12. In FIG. 14, a solid line, a dotted line, a broken line, an alternate long and short dash line, along dash line, and an alternate long and two short dashes line represent relationships between the temperature and the distance from the rotational center P of the rotary table 12 of the low resistance silicon wafers loaded in Slot1, Slot2, Slot3, Slot4, Slot5, and Slot6, respectively.

As shown in FIG. 14, the six sheets of the low resistance silicon wafers had almost the same temperature at any positions thereof in the diameter direction of the rotary table 12, and a temperature difference at the position where there is the largest temperature difference (the position of about 340 mm in FIG. 14) was 0.5 degrees C.

### Example 4

In Example 4, the temperature measurement was performed by the same temperature measuring method as Example 3 except that six sheets of N-type silicon wafers doped with Sb (antimony) as impurities and having a resistivity of 0.02 Ω·cm at room temperature were employed as the low resistance silicon wafers. In addition, the six sheets of silicon wafers used were manufactured from different ingots from one another.

FIG. 15 is a graph showing a relationship between a position in a diameter direction and a temperature of a rotary table in Example 4. In the graph of FIG. 14, the horizontal axis represents the distance (mm) from the rotational center P of the rotary table 12, and the vertical axis represents the temperature (degrees C.). In addition, a range in which the low resistance silicon wafer is loaded is within a distance of 160 mm or more and 460 mm or less from the rotational center P of the rotary table 12.

Specifically, FIG. 15 shows temperature distributions of the six sheets of the low resistance silicon wafers in the diameter direction of the rotary table 12 when the low resistance silicon wafers have been respectively loaded in the six concave portions 16 of the rotary table 12. In FIG. 15, a solid line, a dotted line, a broken line, an alternate long and short dash line, a long dash line, and an alternate long and two short dashes line represent relationships between the temperature and the distance from the rotational center P of the rotary table 2 of the low resistance silicon wafers loaded in Slot1, Slot2, Slot3, Slot4, Slot5, and Slot6, respectively.

As shown in FIG. 15, the six sheets of the low resistance silicon waters had almost the same temperature at any positions thereof in the diameter direction of the rotary table 12, and a temperature difference at the position where there is the largest temperature difference (the position of about 440 mm in FIG. 15) was 0.7 degrees C.

In addition, as shown in FIG. 15, at the position (in FIG. 15) Where a distance from the rotational center P of the rotary table 12 is 370 mm, a variation in temperature, which is not shown in FIG. 14, was confirmed. It is thought that this is because the low resistance silicon water doped with Sb as impurities transmits some amounts of infrared rays at a low temperature and hence some of the infrared rays radiated from the lifting pins, the heater 20 and the like disposed below the low resistance silicon wafer transmit through the low resistance silicon wafer and enter the radiation temperature measurement part 3.

### Comparative Example 1

In Comparative Example 1, the temperature measurement was performed by the same temperature measuring method as Example 2 except that SiC wafers were employed instead of the low resistance silicon wafers. In addition, the six sheets of SiC wafers used were manufactured from ingots that are different from one another.

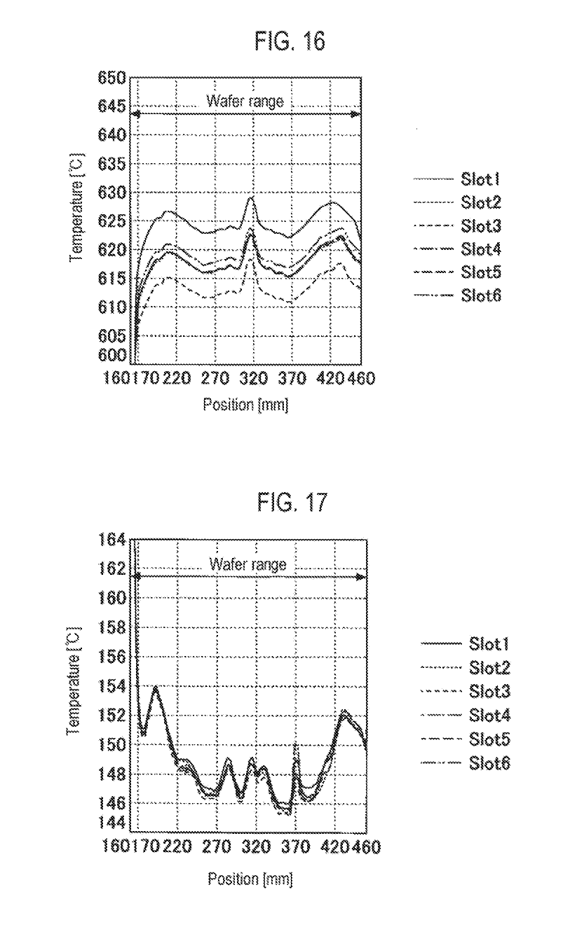

FIG. 16 is a graph showing a relationship between a position in a diameter direction and a temperature of a rotary table in Comparative Example 1. In the graph of FIG. 16, the horizontal axis represents the distance (mm) from the rotational center P of the rotary table 12, and the vertical axis represents the temperature (degrees C.). In addition, a range in which the SiC wafer is loaded is within a distance of 160 mm or more and 460 mm or less from the rotational center P of the rotary table 12.

Specifically, FIG. 16 shows temperature distributions of the six sheets of the SIC wafers in the diameter direction of the rotary table 12 when the SiC wafers have been respectively loaded in the six concave portions 16 of the rotary table 12. In FIG. 16, a solid line, a dotted line, a broken line, an alternate long and short dash line, a long dash line, and an alternate long and two short dashes line represent relationships between the temperature and the distance from the rotational center P of the rotary table 12 of the SiC waters loaded in Slot1, Slot2, Slot3, Slot4, Slot5, and Slot6, respectively.

As shown in FIG. 16, differences between temperatures measured from the six sheets of the SiC wafers were large at almost all positions in the diameter direction of the rotary table 12, and a temperature difference at the position where the distance from the rotational center P of the rotary table 12 is 420 mm was 12 degrees C. This temperature difference was ten or more times larger than 0.9 degrees C. of Example 2.

### Comparative Example 2

In Comparative Example 2, the temperature measurement was performed by the same temperature measuring method as Example 3 except that high resistance silicon wafers were employed instead of the low resistance silicon wafers. Six sheets of P-type silicon wafers doped with B and having a resistivity of 1 Ω·cm or more and 50 Ω·cm or less at room temperature were employed as the high resistance silicon wafers. In addition, the six sheets of silicon wafers used were manufactured from different ingots from one another.

FIG. 17 is a graph showing a relationship between a position in a diameter direction and a temperature of a rotary table in Comparative Example. In the graph of FIG. 17, the horizontal axis represents the distance (mm) from the rotational center P of the rotary table 12, and the vertical axis represents the temperature (degrees C.). In addition, a range in which the high resistance silicon wafer is loaded is within a distance of 160 mm or more and 460 mm or less from the rotational center P of the rotary table 12.

Specifically, FIG. 17 shows temperature distributions of the six sheets of the Ugh resistance silicon wafers in the diameter direction of the rotary table 12 when the high resistance silicon wafers have been respectively loaded in the six concave portions 16 of the rotary table 12. In FIG. 17, a solid line, a dotted line, a broken line, an alternate long and short dash line, a long dash line, and an alternate long and two short dashes line represent relationships between the temperature and the distance from the rotational center P of the rotary table 12 of the high resistance silicon wafers loaded in Slot1, Slot2, Slot3, Slot4, Slot5, and Slot6, respectively.

As shown in FIG. 17, it was confirmed that when the high resistance silicon wafers were employed, the temperatures measured for the set temperature (155 degrees C.) of the heater 20 at almost all positions in the diameter direction of the rotary table 12 were generally lowered. It is thought that this is because the high resistance silicon wafer does not radiate infrared rays at a low temperature and hence the amount of infrared rays radiated from the high resistance silicon wafer and incident on the radiation temperature measurement part 3 is small. In addition, as shown in FIG. 17, it was confirmed that measured temperatures differed considerably according to the distance from the rotational center P of the rotary table 12. It is thought that this is because the high resistance silicon wafer transmits infrared rays at a low temperature and hence the infrared rays radiated from the lifting pins, the heater 20 and the like disposed below the high resistance silicon wafer transmit through the high resistance silicon wafer and enter the radiation temperature measurement part 3.

It could be confirmed from the results of Example 2 and Comparative Example 1 and the results of Examples 3 and 4 and Comparative Example 2 described above that, by using low resistance silicon wafers having a sufficiently low resistivity, even when the wafers are manufactured from different ingots from one another, a deviation between the temperatures measured from the respective wafers could be suppressed. That is, even when wafers having different manufacturing histories are used, it is possible to measure temperatures of the wafers with high precision.

In addition, it could be confirmed from the results of Examples 1 to 3 that, in a temperature range from a low temperature (e.g., 155 degrees C.) up to a high temperature (e.g., 760 degrees C.), a deviation between the temperatures measured from the respective wafers could be suppressed. That is, in a temperature range from the low temperature up to the high temperature, temperatures of wafers can be measured with high precision.

As described above, according to the temperature measuring method and the heat processing apparatus of the present embodiments, even when waters having different manufacturing histories are used, it is possible to measure temperatures of the wafers with high precision.

Further, in each of the above-described embodiments, the wafer is an example of a substrate, and the wafer boat is an example of a substrate holder.

While the temperature measuring method and the heat processing apparatus have been described with Examples, the present disclosure is not limited to the above-described Examples and various changes and modifications may be made within the scope of the present disclosure.

While in each embodiment, the P-type silicon wafer doped with B as impurities and the N-type silicon wafer doped with Sb as impurities have been described as the low resistance silicon wafer, the present disclosure is not limited thereto. Any silicon wafer doped with a trivalent or pentavalent element as impurities may be used as the low resistance silicon wafer. The trivalent element may include, for example, (aluminum), and the pentavalent element may include, for example, P (phosphorus), or As (arsenic).

In addition, while the cases in which the installation positions of the radiation temperature measurement parts and the like are different have been described in the second to fifth embodiments, the present disclosure is not limited to the configurations of the second to fifth embodiments, and the radiation temperature measurement parts of these embodiments may be combined.

According to the embodiments, it is possible to provide a temperature measuring method capable of measuring temperatures of wafers with high precision.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A temperature measuring method for measuring a temperature in a processing vessel of a semiconductor manufacturing apparatus by a radiation temperature measurement part, which is configured to measure a temperature by detecting infrared rays radiated from an object, the method comprising:
detecting infrared rays radiated from a low resistance silicon wafer having a resistivity of 0.02 Ω·cm or less at room temperature (20 degrees C.) by the radiation temperature measurement part.

2. The method of claim 1, wherein the low resistance silicon wafer is a silicon wafer doped with a trivalent or pentavalent element as impurities.

3. The method of claim 1, wherein the low resistance silicon wafer is held by a substrate holder configured to hold substrates to be processed in the processing vessel.

4. The method of claim 3, wherein the substrate holder holds the substrates with a predetermined interval a vertical direction, and the low resistance silicon wafer is disposed at the uppermost end or the lowermost end of the substrate holder in the vertical direction.

5. The method of claim 1, wherein the low resistance silicon wafer is fixed to an outer wall of the processing vessel.

6. A temperature measuring method in a heat processing apparatus wherein a plurality of substrates are loaded on a surface of a rotary table installed in a processing vessel and a heat process is performed on the plurality of substrates while rotating the rotary table, the method comprising:
loading a plurality of low resistance silicon wafers having a resistivity of 0.02 Ω·cm or less at room temperature (20 degrees C.) on the surface of the rotary table;
rotating the rotary table having the plurality of low resistance silicon wafers loaded thereon; and
measuring temperatures of the low resistance silicon wafers by detecting infrared rays radiated from surfaces of the respective low resistance silicon wafers while the rotary table is rotated.

7. The method of claim 6, wherein measuring temperatures of the low resistance silicon wafers includes measuring temperatures in a plurality of regions along a diameter direction of the rotary table.

8. The method of claim 6, wherein the low resistance silicon wafers is a silicon wafer doped with a trivalent or pentavalent element as impurities.

9. The method of claim 6, wherein measuring temperatures of the low resistance silicon wafers includes measuring the temperatures of the low resistance silicon wafers in a state where the low resistance silicon wafers are heated by a heater.

10. A heat processing apparatus wherein a plurality of substrates are loaded on a surface of a rotary table installed in a processing vessel and a heat process is performed on the plurality of substrates while rotating the rotary table, the apparatus comprising:
a control part configured to perform the following steps in the following order:
loading a plurality of low resistance silicon wafers having a resistivity of 0.02 Ω·cm or less at room temperature (20 degrees C.) on the surface of the rotary table;
rotating the rotary table having the plurality of low resistance silicon wafers loaded thereon; and
measuring temperatures of the low resistance silicon wafers by detecting infrared rays radiated from surfaces of the respective low resistance silicon wafers while the rotary table is rotated.
